(19) United States
(12) Patent Application Publication
(10) Pub. No.: US 2006/0102954 A1
(43) Pub. Date: May 18, 2006

(54) Organic thin film transistor array panel and manufacturing method thereof

(75) Inventors: Min-Seong Ryu, Gyeonggi-do (KR); Jong-Hyun Seo, Seoul (KR); Mun-Pyo Hong, Gyeonggi-do (KR)

Correspondence Address: PATENT LAW GROUP LLP, 2635 NORTH FIRST STREET, SUITE 223, SAN JOSE, CA, 95134, US

(73) Assignee: Samsung Electronics Co., LTD.

(21) Appl. No.: 11/236,111

(22) Filed: Sep. 26, 2005

(30) Foreign Application Priority Data
Nov. 16, 2004 (KR) 10-2004-0093561

(51) Int. Cl. H01L 21/00; H01L 21/84

(52) U.S. Cl. 257/347; 438/149; 438/82

(57) ABSTRACT

A method of manufacturing a thin film transistor array panel is provided, the method includes: forming a gate line on a substrate; forming a gate insulating layer on the gate line; depositing an ITO layer at a temperature of about 20-35° C.; etching the ITO layer to form a data line and a drain electrode on the gate insulating layer; and forming an organic semiconductor on the data line, the drain electrode, and the gate insulating layer.

### BACKGROUND OF THE INVENTION

(a) Field of the Invention

The present invention relates to a thin film transistor array panel and a manufacturing method thereof, and in particular, to an organic thin film transistor array panel and a manufacturing method thereof.

(b) Description of Related Art

Electric field effect transistors including organic semiconductors have been vigorously researched as driving devices for next generation display devices. Organic semiconductors may be classified into low molecule compounds such as oligothiophene, pentacene, phthalocyanine, and C₆O; and high molecule compounds such as polythiophene and polythienylenevinylene. The low molecule semiconductors have a high mobility in a range of about 0.05-1.5 msV, and superior on/off current ratios.

However, conventional processes for manufacturing organic thin film transistors (TFTs), including low molecule semiconductor compounds, can be complicated in that they require a low molecule semiconductor pattern be formed by using a shadow mask and vacuum deposition in order to avoid solvent-induced, in-plane expansion caused by organic solvents.

In addition, the organic semiconductor is prone to change its characteristics or to be damaged by subsequent processing steps, thereby deteriorating the characteristics of organic TFTs.

Therefore, the organic semiconductor has to be formed after the signal lines for transmitting signals to the organic TFTs are formed.

The material of signal lines is determined in consideration of the contact with the organic semiconductor. Examples of such a material include gold (Au), molybdenum (Mo), nickel (Ni), and alloys thereof. Although Au has low resistivity and exhibits stable contact with the organic semiconductor, it has a poor contact characteristic with insulator. In addition, although Mo and Ni have large work function, it is apt to form oxides on their surfaces, which degrade the current characteristics of the TFT.

Recently, indium tin oxide (ITO) is suggested to be a material of the signal lines for organic TFTs, which is free of surface oxidation and shows excellent contact with organic semiconductor.

However, ITO is in poor contact with insulator, in particular, with organic insulator and thus it is difficult to employ ITO signal lines especially in large display devices.

### SUMMARY OF THE INVENTION

A method of manufacturing a thin film transistor array panel is provided, the method includes: forming a gate line on a substrate; forming a gate insulating layer on the gate line; depositing an ITO layer at a temperature of about 20-35° C.; etching the ITO layer to form a data line and a drain electrode on the gate insulating layer; and forming an organic semiconductor on the data line, the drain electrode, and the gate insulating layer.

The deposition of the ITO layer may include: sputtering the ITO layer at a temperature of about 20-35° C. to form a sputtered ITO layer.

The sputtered ITO layer may include an amorphous ITO layer and may have substantially uniform film quality.

The gate insulating layer may include an organic insulator.

The method may further include: annealing the data line and the drain electrode. The annealing may be performed at a temperature higher than about 180° C. for about one to three hours. The annealed data line and the annealed drain electrode may include a quasi-crystalline ITO.

The etching of the ITO layer may include: wet etching the ITO layer with preferably a Cr etchant that may include HNO₃, (NH₄)₂Ce(NO₃)₆, and H₂O. The proportions of HNO₃, (NH₄)₂Ce(NO₃)₆, and H₂O in the etchant may be equal to about 3-6 w %, about 8-14 w %, and about 80-90 w %, respectively, in weight percentage.

The method may further include: forming a passivation layer on the organic semiconductor, the data line, and the drain electrode, the passivation layer having a contact hole exposing the drain electrode at least in part; and forming a pixel electrode on the passivation layer, the pixel electrode connected to the drain electrode through the contact hole.

A thin film transistor array panel is provided, which includes: a gate line formed on a substrate; an organic insulating layer formed on the gate line; a data line and a drain electrode that are formed on the organic insulating layer and include an ITO layer; an organic semiconductor formed on the data line, the drain electrode, and the organic insulating layer; a passivation layer formed on the organic semiconductor; and a pixel electrode connected to the drain electrode.

The ITO layer may be in quasi-crystalline phase that is substantially uniformly distributed from bottom to top of the ITO layer.

The ITO layer may have an inclined edge profile.

The organic semiconductor may include pentacene.

### BRIEF DESCRIPTION OF THE DRAWINGS

The present invention will become more apparent by describing embodiments thereof in detail with reference to the accompanying drawing in which:

FIG. 1 is a layout view of a TFT array panel for an LCD according to an embodiment of the present invention;

FIG. 2 is a sectional view of the TFT array panel shown in FIG. 1 taken along the line II-II′;

FIGS. 3, 5, 8, 10 and 12 are layout views of a TFT array panel shown in FIGS. 1 and 2 in intermediate steps of a manufacturing method thereof according to an embodiment of the present invention;

FIG. 4 is a sectional view of the TFT array panel shown in FIG. 3 taken along the line IV-IV′;

FIG. 6 is a sectional view of the TFT array panel shown in FIG. 5 taken along the line VI-VI′;

FIG. 7 is a photograph illustrating a section of layers after etching an ITO layer using a Cr etchant;

FIG. 9 is a sectional view of the TFT array panel shown in FIG. 8 taken along the line IX-IX′;

FIG. 11 is a sectional view of the TFT array panel shown in FIG. 10 taken along the line XI-XI′; and

FIG. 13 is a sectional view of the TFT array panel shown in FIG. 12 taken along the line XIII-XIII′.

### DETAILED DESCRIPTION OF EMBODIMENTS

The present invention now will be described more fully hereinafter with reference to the accompanying drawings, in which preferred embodiments of the invention are shown. This invention may, however, be embodied in many different forms and should not be construed as limited to the embodiments set forth herein.

In the drawings, the thickness of layers and regions are exaggerated for clarity. Like numerals refer to like elements throughout. It will be understood that when an element such as a layer, region or substrate is referred to as being “on” another element, it can be directly on the other element or intervening elements may also be present. In contrast, when an element is referred to as being “directly on” another element, there are no intervening elements present.

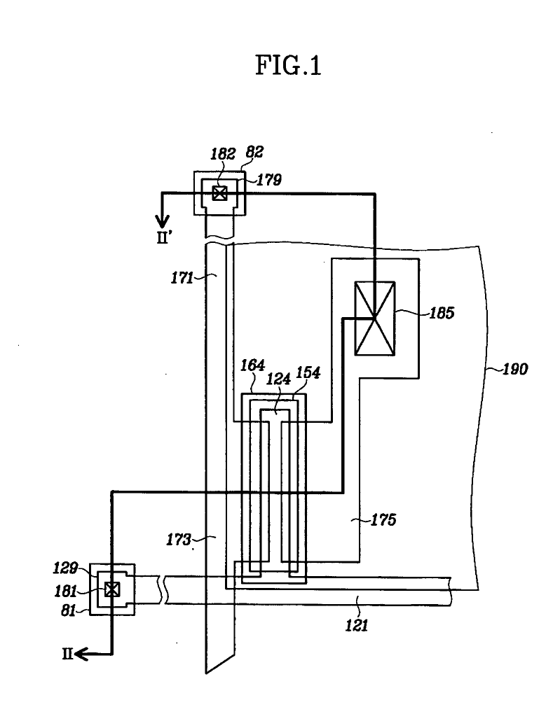

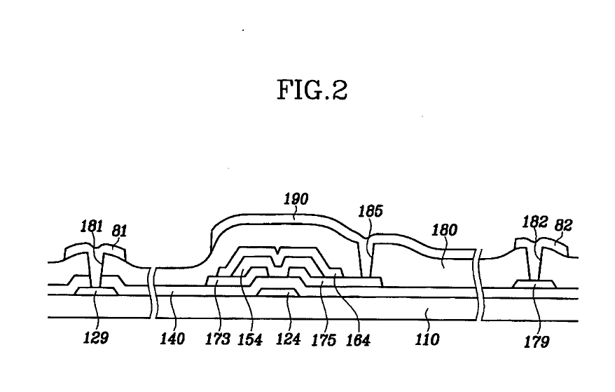

A TFT array panel according to an embodiment of the present invention will be described with reference to FIGS. 1 and 2.

FIG. 1 is a layout view of a TFT array panel for an LCD according to an embodiment of the present invention, and FIG. 2 is a sectional view of the TFT array panel shown in FIG. 1 taken along the line II-II′.

A plurality of gate lines 121 are formed on an insulating substrate 110 such as transparent glass, silicone, or plastic.

The gate lines 121 transmit gate signals and extend substantially in a transverse direction. Each gate line 121 includes a plurality of gate electrodes 124 projecting upward and an end portion 129 having a large area for contact with another layer or an external driving circuit. A gate driving circuit (not shown) for generating the gate signals may be mounted on a flexible printed circuit (FPC) film, which may be attached to the substrate 110, directly mounted on the substrate 110, or integrated onto the substrate 110. The gate lines 121 may extend to be connected to a driving circuit that may be integrated on the substrate 110.

The gate lines 121 are preferably made of Al containing metal such as Al and Al alloy, Ag containing metal such as Ag and Ag alloy, Au containing metal such as Au and Au alloy, Cu containing metal such as Cu and Cu alloy, Mo containing metal such as Mo and Mo alloy, Cr, Ti or Ta. However, they may have a multi-layered structure including two conductive films (not shown) having different physical characteristics. One of the two films is preferably made of low resistivity metal including Al containing metal, Ag containing metal, and Cu containing metal for reducing signal delay or voltage drop. The other film is preferably made of material such as Mo containing metal, Cr, Ta or Ti, which has good physical, chemical, and electrical contact characteristics with other materials such as indium tin oxide (ITO) or indium zinc oxide (IZO). Good examples of the combination of the two films are a lower Cr film and an upper Al (alloy) film and a lower Al (alloy) film and an upper Mo (alloy) film. However, the gate lines 121 may be made of various metals or conductors.

The lateral sides of the gate lines 121 are inclined relative to a surface of the substrate, and the inclination angle thereof ranges about 30-80 degrees.

A gate insulating layer 140 is formed on the gate lines 121. The gate insulating layer 140 is preferably made of inorganic insulator or organic insulator. Examples of the inorganic insulator include silicon nitride (SiNx) and silicon dioxide (SiO₂) that may have a surface treated with octadecyl-trichloro-silane (OTS). Examples of the organic insulator include maleimide-styrene, polyvinylphenol (PVP), and modified cyanoethyl pullulan (m-CEP). It is preferable that the gate insulating layer 140 has good contact characteristics with organic semiconductor and small roughness.

A plurality of data lines 171 and a plurality of drain electrodes 175 are formed on the gate insulating layer 140.

The data lines 171 transmit data signals and extend substantially in a longitudinal direction to intersect the gate lines 121. Each of the data lines 171 includes a plurality of source electrodes 173 projecting toward the gate electrodes 124 and an end portion 179 having a large area for contact with another layer or an external driving circuit. A data driving circuit (not shown) for generating the data signals may be mounted on a flexible printed circuit (FPC) film, which may be attached to the substrate 110, directly mounted on the substrate 110, or integrated onto the substrate 110. The data lines 171 may extend to be connected to a driving circuit that may be integrated on the substrate 110.

The drain electrodes 175 are separated from the data lines 171 and disposed opposite the source electrodes 175 with respect to the gate electrodes 124.

The data lines 171 and the drain electrodes 175 are preferably made of materials having good physical, chemical, and electrical contact characteristics with the gate insulating layer 140 and organic semiconductor. In one embodiment, the data lines 171 and the drain electrodes 175 are made of a material which includes ITO. ITO for the data lines 171 and the drain electrodes 175 has high work function and it may be quasi-crystalline, particularly at the interface with the gate insulating layer 140, to provide excellent contact characteristics with an organic gate insulating layer 140.

The data lines 171 and the drain electrodes 175 have smooth inclined edge profiles.

A plurality of organic semiconductor islands 154 are formed on the source electrodes 173, the drain electrodes 175 and the gate insulating layer 140.

The organic semiconductor islands 154 fully cover the gate electrodes 124 such that the edges of the gate electrodes 124 overlap the organic semiconductor islands 154.

The organic semiconductor islands 154 may include a high molecular compound or a low molecular compound that is soluble in an aqueous solution or organic solvent and in this case, the organic semiconductor islands 154 can be formed by printing.

The organic semiconductor islands 154 may be made of, or formed from derivatives of, tetracene or pentacene with substituent. Alternatively, the organic semiconductor islands 154 may be made of oligothiophene including four to eight thiophenes connected at the positions 2, 5 of thiophene rings.

The organic semiconductor islands 154 may be made of perylenetetracarboxylic dianhydride (PTCDA), naphthalenetetracarboxylic dianhydride (NTCDA), or their imide derivatives.

The organic semiconductor islands 154 may be made of metallized phthalocyanine or halogenated derivatives thereof. The metallized phthalocyanine may include Cu, Co, Zn, etc.

The organic semiconductor islands 154 may be made of co-oligomer or co-polymer of thienylene and vinylene. In addition, organic semiconductor islands 154 may be made of regioregular polythiophene.

The organic semiconductor islands 154 may be made of perylene, coronene or derivatives thereof with substituent.

The organic semiconductor islands 154 may be made of derivatives of aromatic or heteroaromatic ring of the above-described derivatives with at least one hydrocarbon chain having one to thirty carbon atoms.

A gate electrode 124, a source electrode 173, and a drain electrode 175 along with an organic semiconductor island 154 form an organic TFT having a channel formed in the organic semiconductor island 154 disposed between the source electrode 173 and the drain electrode 175. The gate insulating layer 140, which is disposed between the gate electrode 124 and the organic semiconductor island 154, may be made of material having good contact characteristics with the organic semiconductor island 154 and generating minimum leakage current in the TFT.

A plurality of protective members 164 are formed on the semiconductor islands 154. The protective members 164 are preferably made of insulating material that can be dry processed and deposited under low temperature. An example of such a material is parylene that can be formed at room temperature or low temperature. The protective members 164 protect the organic semiconductor islands 154 from being damaged in the manufacturing process. The protective members 164 substantially fully cover the organic semiconductor islands 154 such that the edges of the organic semiconductor islands 154 are covered by the protective members 164. The protective members 164 may be omitted.

A passivation layer 180 is formed on the data lines 171, the drain electrodes 175, and the protective members 164. The passivation layer 180 is preferably made of inorganic insulator such as silicon nitride or silicon oxide, organic insulator, or low dielectric insulator. The organic insulator and the low dielectric insulator preferably have dielectric constant less than about 4.0 and the low dielectric insulator includes a-Si:C:O and a-Si:O:F formed by plasma enhanced chemical vapor deposition (PECVD). The organic insulator for the passivation 180 may have photosensitivity and the passivation 180 may have a flat surface.

The passivation layer 180 has a plurality of contact holes 182 and 185 exposing the end portions 179 of the data lines 171 and the drain electrodes 175, respectively. The passivation layer 180 and the gate insulating layer 140 have a plurality of contact holes 181 exposing the end portions 129 of the gate lines 121.

A plurality of pixel electrodes 190 and a plurality of contact assistants 81 and 82 are formed on the passivation layer 180. They are preferably made of transparent conductor such as ITO or IZO or reflective conductor such as Ag or Al.

The pixel electrodes 191 are physically and electrically connected to the drain electrodes 175 through the contact holes 185 such that the pixel electrodes 191 receive data voltages from the drain electrodes 175. The pixel electrodes 191 supplied with the data voltages generate electric fields in cooperation with a common electrode (not shown) of an opposing display panel (not shown) supplied with a common voltage, which determine the orientations of liquid crystal molecules (not shown) of a liquid crystal layer (not shown) disposed between the two electrodes. A pixel electrode 191 and the common electrode form a capacitor referred to as a “liquid crystal capacitor,” which stores applied voltages after the TFT turns off.

The pixel electrodes 190 overlap the gate lines 121 and the data lines 171 to increase aperture ratio.

The contact assistants 81 and 82 are connected to the end portions 129 of the gate lines 121 and the end portions 179 of the data lines 171 through the contact holes 181 and 182, respectively. The contact assistants 81 and 82 protect the end portions 129 and 179 and enhance the adhesion between the end portions 129 and 179 and external devices.

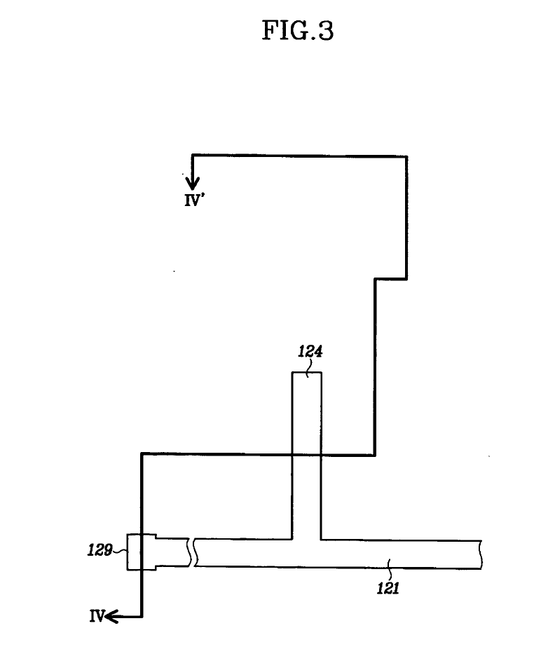

Now, a method of manufacturing the organic TFT array panel shown in FIGS. 1 and 2 according to an embodiment of the present invention will be described in detail with reference to FIGS. 3-13 as well as FIGS. 1 and 2.

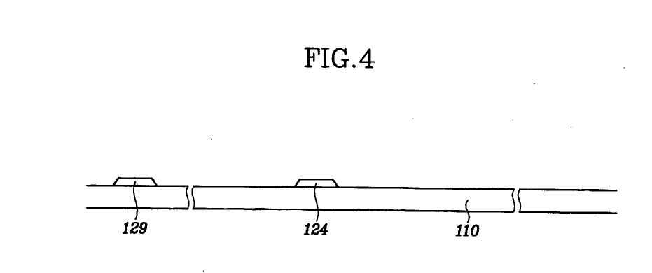

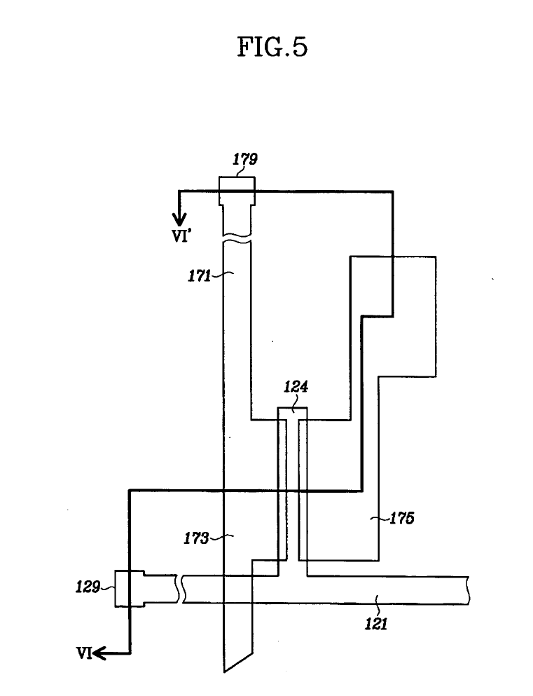

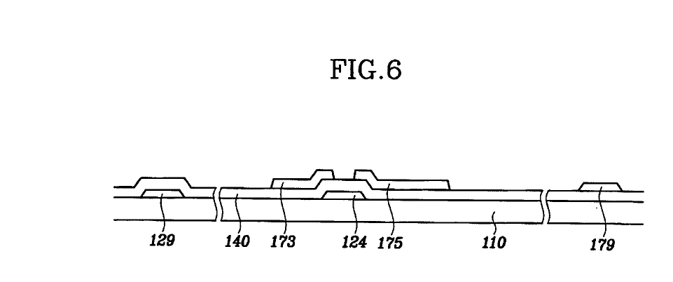

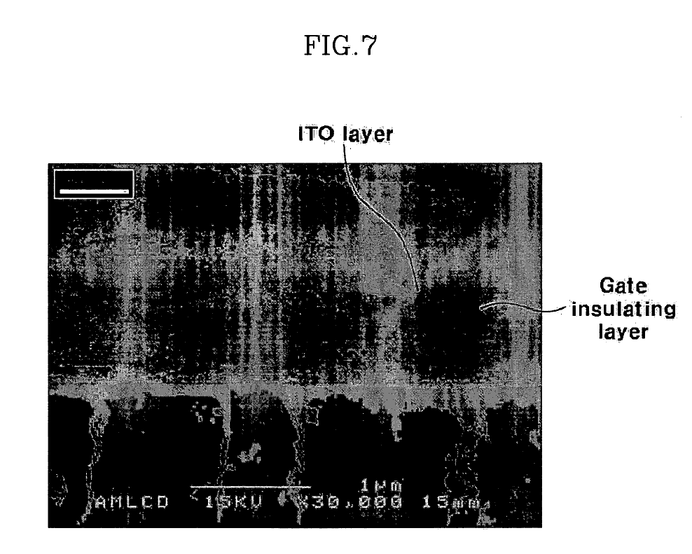

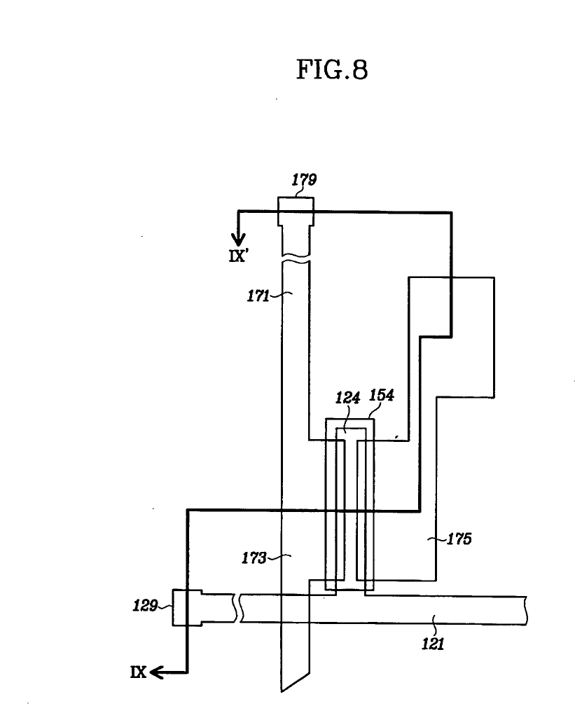

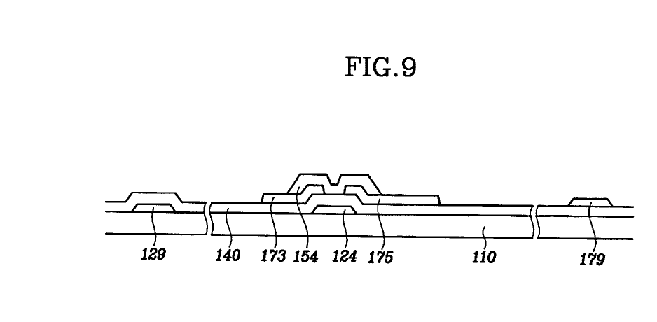

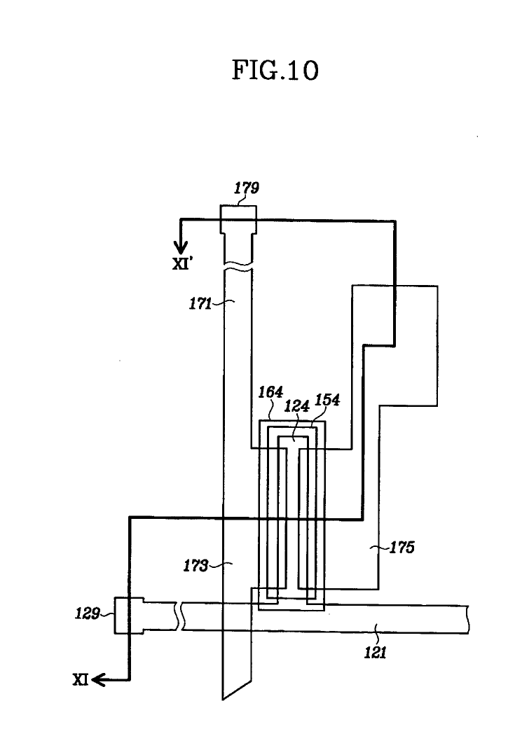

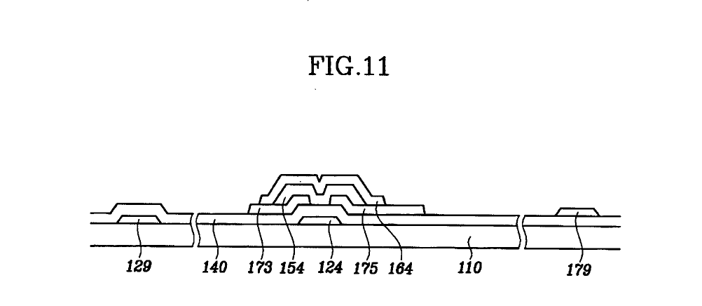

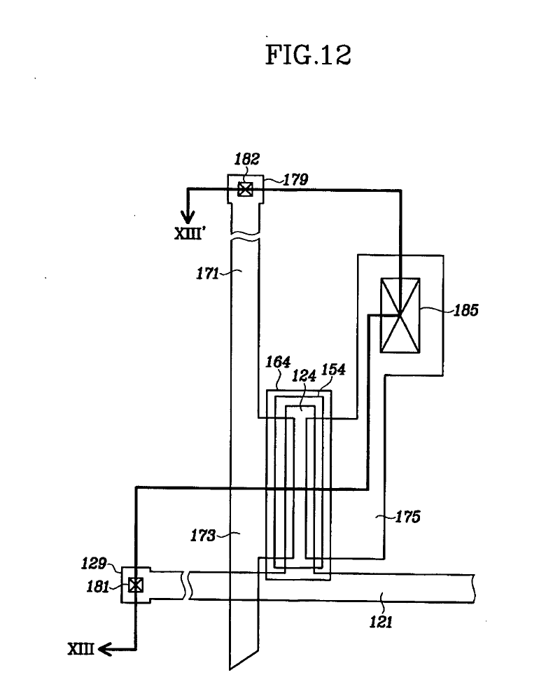

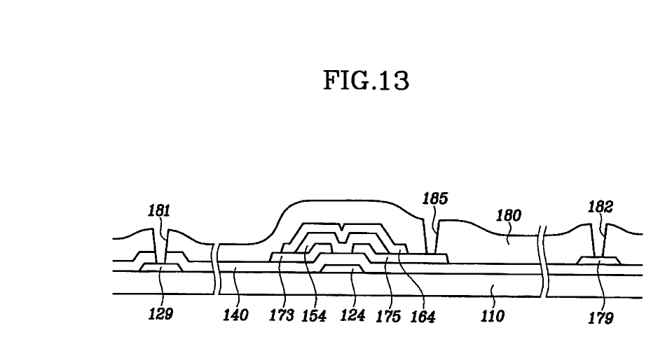

FIGS. 3, 5, 8, 10 and 12 are layout views of the organic TFT array panel shown in FIGS. 1 and 2 in intermediate steps of a manufacturing method thereof according to an embodiment of the present invention. FIG. 4 is a sectional view of the TFT array panel shown in FIG. 3 taken along line IV-IV′, FIG. 6 is a sectional view of the TFT array panel shown in FIG. 5 taken along line VI-VI′, FIG. 9 is a sectional view of the TFT array panel shown in FIG. 8 taken along line IX-IX′, FIG. 11 is a sectional view of the TFT array panel shown in FIG. 10 taken along line XI-XI′, and FIG. 13 is a sectional view of the TFT array panel shown in FIG. 12 taken along line XIII-XIII′. FIG. 7 is a photograph illustrating a section of layers after etching an ITO layer using a Cr etchant.

Referring to FIGS. 3 and 4, a plurality of gate lines 121 that include gate electrodes 124 and end portions 129 are formed on an insulating substrate 110 that is preferably made of transparent glass, silicone, or plastic.

Referring to FIGS. 5 and 6, a gate insulating layer 140 is deposited by CVD, etc. The gate insulating layer 140 may have a thickness of about 500-3,000 Å and it may be dipped in OTS.

Thereafter, a conductive layer preferably made of ITO is deposited on the gate insulating layer by sputtering, etc. The sputtering is performed at a room temperature ranging about 20-35° C. such that the sputtered ITO layer is an amorphous phase and has uniform film quality from the bottom to the top.

Subsequently, the conductive layer is then patterned by lithography and wet etching to form a plurality of data lines 171 including source electrodes 173 and end portions 179 and a plurality of drain electrodes 175. An example of an etchant for the wet etch includes a Cr etchant containing HNO₃, (NH₄)₂Ce(NO₃)₆, and H₂O, which is used for etching Cr. The proportions of HNO₃, (NH₄)₂Ce(NO₃)₆, and H₂O are preferably equal to about 3-6 w %, about 8-14 w %, and about 80-90 w %, respectively, in weight percentage.

Since the film quality is uniform, the etchant uniformly etches the conductive layer, thereby preventing the loss of the conductive layer caused by non-uniform etch.

On the contrary, when the sputtering temperature is higher than about 100° C., the sputtered ITO layer includes a lower amorphous portion near the interface with the gate insulating layer 140 and a remaining quasi-crystalline portion. In this case, the amorphous lower portion having lower density than the quasi-crystalline upper portion may be etched more than the quasi-crystalline upper portion such that portions of the ITO layer are unintentionally removed.

The use of the Cr etchant used for etching amorphous ITO can reduce the damage on the gate insulating layer 140 that may be organic. On the contrary, a quasi-crystalline ITO may require an etchant containing hydrochloric acid that may damage the gate insulating layer 140.

FIG. 7 shows a section of an ITO layer after being etched by a Cr etchant, which shows no lost portion of the ITO layer. The ITO layer is shown to be well patterned to have smooth edge profile.

Next, the data lines 171 and the drain electrodes 175 are annealed to be quasi-crystallized. The annealing is performed preferably at a temperature higher than about 180° C. for about one to three hours.

Referring to FIGS. 8 and 9, an organic semiconductor layer preferably made of pentacene is deposited by molecular beam deposition, vapor deposition, vacuum sublimation, CVD, PECVD, reactive deposition, sputtering, spin coating, etc., and patterned by lithography and etching to form a plurality of organic semiconductor islands 154.

Referring to FIGS. 10 and 11, an insulating layer is dry deposited on the organic semiconductor islands 154 at low temperature or room temperature. The insulating layer may be made of parylene. The low-temperature dry deposition of the insulating layer prevents the organic semiconductor islands 154 from being damaged. The insulating layer is subjected to lithography and dry etch to form a plurality of protective members 164. The protective members 164 fully cover the organic semiconductor islands 154.

Referring to FIGS. 12 and 13, a passivation layer 180 is deposited and patterned along with the gate insulating layer 140 to form a plurality of contact holes 181, 182 and 185 exposing the end portions 129 of the gate lines 121, the end portions 179 of the data lines 171, and portions of the drain electrodes 175, respectively. Since the organic semiconductor islands 154 are fully covered by the protective members 164, the organic semiconductor islands 154 do not be affected by the formation of the passivation layer 180.

Finally, a plurality of pixel electrodes 190 and a plurality of contact assistants 81 and 82 are formed on the passivation layer 180 as shown in FIGS. 1 and 2. At this time, the organic semiconductor islands 154 will not be affected by the formation of the pixel electrodes 190 and the contact assistants 81 and 82 since the organic semiconductor islands 154 are not exposed.

As described above, since the ITO layer is deposited to have uniform film quality, it is uniformly etched to prevent the loss of the ITO layer. Furthermore, since the ITO layer is deposited in amorphous phase, it can be etched by a Cr etchant that may not attack an organic layer under the ITO layer.

The present invention can be employed to any display devices including LCD and OLED display.

Although preferred embodiments of the present invention have been described in detail hereinabove, it should be clearly understood that many variations and/or modifications of the basic inventive concepts herein taught which may appear to those skilled in the present art will still fall within the spirit and scope of the present invention, as defined in the appended claims.

What is claimed is:

1. A method of manufacturing a thin film transistor array panel, the method comprising:
forming a gate line on a substrate;
forming a gate insulating layer on the gate line;
depositing an ITO layer at a temperature of about 20-35° C.;
etching the ITO layer to form a data line and a drain electrode on the gate insulating layer; and
forming an organic semiconductor on the data line, the drain electrode, and the gate insulating layer.

2. The method of claim 1, wherein the depositing the ITO layer comprises:
sputtering the ITO layer at a temperature of about 20-35° C. to form a sputtered ITO layer.

3. The method of claim 2, wherein the sputtered ITO layer comprises an amorphous ITO layer.

4. The method of claim 3, wherein the sputtered ITO layer has substantially uniform film quality.

5. The method of claim 1, wherein the gate insulating layer comprises an organic insulator.

6. The method of claim 1, further comprising:
annealing the data line and the drain electrode.

7. The method of claim 6, wherein the annealing is performed at a temperature higher than about 180° C.

8. The method of claim 7, wherein the annealing is performed for about one to three hours.

9. The method of claim 6, wherein the annealed data line and the annealed drain electrode comprise a quasi-crystalline ITO.

10. The method of claim 1, wherein the etching of the ITO layer comprises:
wet etching the ITO layer with an etchant.

11. The method of claim 10, wherein the etchant comprises a Cr etchant.

12. The method of claim 10, wherein the etchant comprises HNO₃, (NH₄)₂Ce(NO₃)₆, and H₂O.

13. The method of claim 12, wherein proportions of HNO₃, (NH₄)₂Ce(NO₃)₆, and H₂O in the etchant are equal to about 3-6 w %, about 8-14 w %, and about 80-90 w %, respectively, in weight percentage.

14. The method of claim 1, further comprising:
forming a passivation layer on the organic semiconductor, the data line, and the drain electrode, the passivation layer having a contact hole exposing the drain electrode at least in part; and
forming a pixel electrode on the passivation layer, the pixel electrode connected to the drain electrode through the contact hole.

15. A thin film transistor array panel comprising:
a gate line formed on a substrate;
an organic insulating layer formed on the gate line;
a data line and a drain electrode that are formed on the organic insulating layer and include an ITO layer;
an organic semiconductor formed on the data line, the drain electrode, and the organic insulating layer;
a passivation layer formed on the organic semiconductor; and
a pixel electrode connected to the drain electrode.

16. The thin film transistor array panel of claim 15, wherein the ITO layer is in quasi-crystalline phase.

17. The thin film transistor array panel of claim 16, wherein the quasi-crystalline phase of the ITO layer is substantially uniformly distributed from bottom to top of the ITO layer.

18. The thin film transistor array panel of claim 15, wherein the ITO layer has an inclined edge profile.

19. The thin film transistor array panel of claim 15, wherein the organic semiconductor comprises pentacene.
